(19) United States
(12) Patent Application Publication
(10) Pub. No.: US 2013/0017659 A1
(43) Pub. Date: Jan. 17, 2013

(54) FABRICATING METHOD OF SEMICONDUCTOR DEVICE

(71) Applicant: An-Chi LIU, Tainan City (TW)

(72) Inventor: An-Chi LIU, Tainan City (TW)

(73) Assignee: UNITED MICROELECTRONICS CORP., HSINCHU (TW)

(21) Appl. No.: 13/179,627

(22) Filed: Jul. 11, 2011

(51) Int. Cl. H01L 21/336

(52) U.S. Cl. 438/296; 257/E21.409

(57) ABSTRACT

A fabricating method of a semiconductor device includes the following actions. A substrate having a silicon gate structure formed thereon is provided, and then a modification process is performed on a surface of the silicon gate structure to render the surface from being hydrophobic to be hydrophilic. After that, a mask is formed on the substrate. In succession, a dopant implantation process is performed using the silicon gate structure after the modification process and the mask. After the dopant implantation process, a cleaning process which includes a wet cleaning process is performed to remove the mask. In the above fabricating method, because the surface of the silicon gate structure is modified into a hydrophilic surface, therefore it is easy to remove the residues after the dopant implantation process using the wet cleaning process.

### FIELD OF THE INVENTION

The present invention relates generally to a fabricating method of a semiconductor device, and more particularly to a fabricating method of a semiconductor device for an integrated circuit.

### BACKGROUND OF THE INVENTION

Metal oxide semiconductor (MOS) transistors are widely used in integrated circuits. In a fabricating method of MOS transistors, the gate structures are usually employed as a mask in an ion implantation process. Moreover, during a fabricating process of complementary metal oxide semiconductor (CMOS) transistors, photoresist material is also required to mask certain areas to implant different dopants in different areas. However, it is usually difficult to completely remove the residues on surfaces of the gate structures and the substrate of the gate structures during the following water washing process for removing the photoresist material. Accordingly, there is a desire to develop a fabricating method of a semiconductor device, in which the residues on the gate structure and the substrate can be easily removed.

### SUMMARY OF THE INVENTION

The present invention provides a fabricating method of a semiconductor device which is capable of easily removing the residues after the dopant implantation process.

In one embodiment, a fabricating method of a semiconductor device includes the following actions. A substrate having a silicon gate structure formed thereon is provided, and then a modification process is performed on a surface of the silicon gate structure to render the silicon surface from being hydrophobic to be hydrophilic. After that, a mask is formed on the substrate. In succession, a dopant implantation process is performed using the silicon gate structure after the modification process and the mask. After the dopant implantation process, a cleaning process which includes a wet cleaning process is performed to remove the mask.

In the above fabricating method, because the surface of the silicon gate structure is modified into a hydrophilic surface, therefore it is easy to remove the residues after the dopant implantation process using the wet cleaning process.

### BRIEF DESCRIPTION OF THE DRAWINGS

The above objects and advantages of the present invention will become more readily apparent to those ordinarily skilled in the art after reviewing the following detailed description and accompanying drawings, in which:

FIGS. 1A to 1F are schematic views illustrating partial steps of a fabricating method of a semiconductor device.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

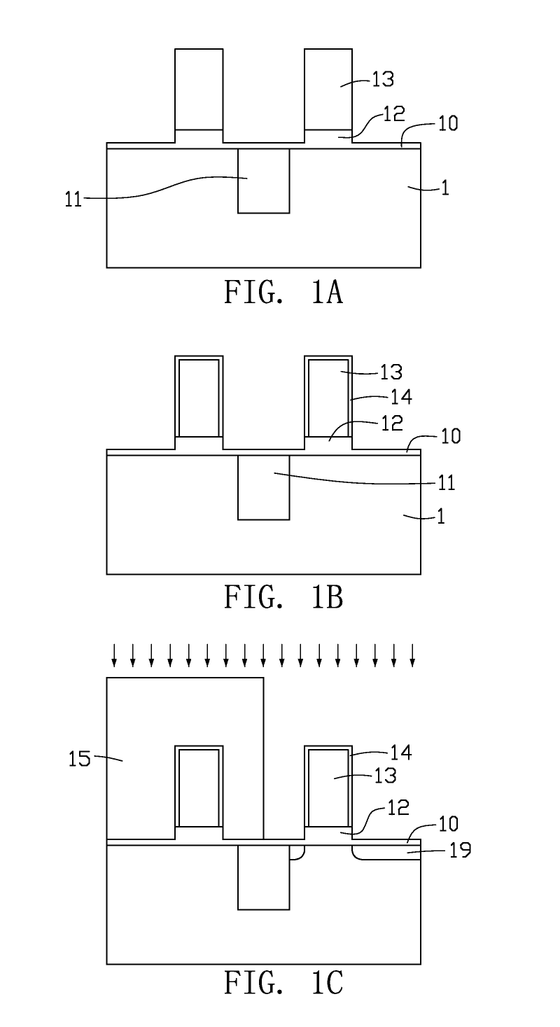

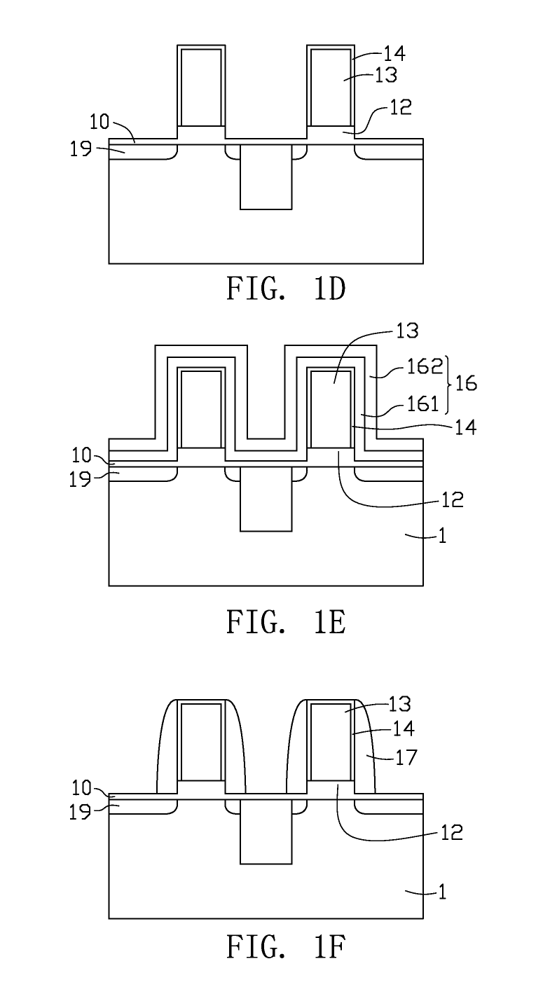

FIGS. 1A to 1F are schematic views illustrating partial steps of a fabricating method of a semiconductor device. First, as shown in FIG. 1A, a shallow trench isolation structure 11 is formed on the substrate 1, and then a gate insulator layer 12 and a silicon gate structure 13 are formed a surface of the substrate 1. During a patterning process for defining the gate silicon gate structure 13, portions of the gate insulator layer 12 that is not covered by the silicon gate structure 13 are also partially etched thereby forming a plurality of depressed remaining portions 10 in the gate insulator layer 12. In addition, the silicon gate structure 13 is a structure includes silicon. For example. The silicon gate structure 13 may include homogeneous, heterogeneous, or gradient polysilicon, monocrystalline silicon, doped silicon, epitaxy layer of silicon and other elements, doped materials such as silicon germanium strained silicon, strained silicon, or any combination thereof. Besides, although the silicon gate structure 13 shown in FIG. 1A has a single layer arrangement, however, the silicon gate structure 13 can also be a multilayer structure or further includes a top dielectric mask layer.

After that, as shown in FIG. 1B, an oxidation process is used to modify a surface of the silicon gate structure 13 thereby changing the surface of the silicon gate structure 13 from hydrophobic to hydrophilic. The oxidation process, for example, is an oxygen radical oxidation process, and the reacting temperature of the oxygen plasma oxidation process is in a range from 200° C. to 300° C. In addition, the oxidation process can also be an furnace oxidation process, and the reacting temperature thereof is in a range from 800° C. to 1000° C. Furthermore, the oxidation process can also be a chemical oxidation process, during which the substrate 1 and the silicon gate structure 13 are immerged in a hydrogen peroxide solution. The temperature of the hydrogen peroxide solution is in a range from 25° C. to 80° C. After the oxidation process, a silicon oxide layer 14 is formed at surfaces of the silicon gate structure and a thickness of the silicon oxide layer 14 is less than 20 angstroms. It is to be noted that this oxidation process consumes a surface layer of the silicon gate structure 13. In another embodiment, the thickness of the silicon oxide layer 14 is in a range from to 20 angstroms. The thickness of the silicon oxide layer 14 should be evaluated according to the demand of the following ion implantation process because thick silicon oxide layer would increase the difficulty of the following ion implantation process. The present invention is not limited to the above oxidation modification process, and any process that is capable of changing the silicon surface into a hydrophilic surface can also be used. In addition, the above described process may use any appropriate process for forming the silicon gate structure. For example, the silicon gate structure may include a top dielectric mask layer and thus only side surfaces of the silicon gate structure are exposed. In other embodiments, the silicon gate structure can also be non-functional gate electrodes, which are removed in the following process and the produced voids can be filled with metals.

In succession, as shown in FIG. 1C, the silicon gate structure 13 having the silicon oxide layer 14 formed in its surface serves as a self-aligned mask, and this self-aligned mask is used in conjunction with a mask consisting of a photoresist material 15 to perform an ion implantation process for implanting dopants thereby forming a P type or an N type doped regions 19. The doped region 19, for example, is a N-type lightly doped region of input/output device (NLIO) or a P-type lightly doped region of input/output device (PLIO).

After the ion implantation process, as shown in FIG. 1D, a cleaning process is used remove the mask consisting of the photoresist material 15. The cleaning process, for example, may include an ash process and a wet cleaning process. The ash process can be performed at a temperature in a range from 25° C. to 300° C. In addition, oxygen gas can be introduced to remove the mask during the ash process. Since there is the hydrophilic silicon oxide layer 14 formed at the surfaces of the silicon gate structure, the residues after the ash process can be easily removed by the wet cleaning process. Thus, the disadvantage of it is difficult to remove the residues is overcome by the method of the present embodiment.

After the cleaning process, as shown in FIG. 1E, a partitioning wall layer 16 is deposited on the substrate 1 and the silicon gate structure 13. The partitioning wall layer 16 can be a single layer or a multilayer structure. In FIG. 1E, the partitioning wall layer 16 is a multilayer structure including a silicon dioxide layer 161 and a silicon nitride layer 162. After that, portions of the partitioning wall layer 16 are removed using an anisotropy etching process to form a portioning wall structure 17 as shown in FIG. 1F. After continuing processes on the structure shown in FIG. 1F, semiconductor devices such as MOS transistors, can be obtained.

It is to be noted that, the oxide layer on the surface of the substrate will be successively removed in the following wet washing processes. Although the wet washing processes are not described above in detail, however, there is usually a wet washing process prior to most film growing/deposition process or after any etching process. These wet washing processes largely consume the oxide layer on the surface of the substrate.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A fabricating method of a semiconductor device, comprising:
providing a substrate having a silicon gate structure formed thereon;
performing a modification process on a surface of the silicon gate structure to render the surface from being hydrophobic to be hydrophilic;
forming a mask on the substrate;
performing a dopant implantation process using the silicon gate structure after the modification process and the mask; and
performing a cleaning process, which includes a wet cleaning process, to remove the mask.

2. The fabricating method of a semiconductor device as claimed in claim 1, wherein the substrate is a silicon substrate, the substrate has a shallow trench isolation structure formed thereon, and a gate insulator layer is formed between the silicon gate structure and the silicon substrate.

3. The fabricating method of a semiconductor device as claimed in claim 1, wherein the modification process comprises:
processing the silicon gate structure with a oxidation process; and
forming a silicon oxide layer on a surface of the silicon gate structure, wherein a thickness of the silicon oxide layer is less than 20 angstroms.

4. The fabricating method of a semiconductor device as claimed in claim 3, wherein the thickness of the silicon oxide layer is in the range from 10 angstroms to 20 angstroms.

5. The fabricating method of a semiconductor device as claimed in claim 3, wherein the oxidation process is an oxygen radical oxidation process at a temperature in a range from 200 ° C. to 300° C.

6. The fabricating method of a semiconductor device as claimed in claim 3, wherein the oxidation process is a furnace oxidation process at a temperature in a range from 800° C. to 1000° C.

7. The fabricating method of a semiconductor device as claimed in claim 3, wherein the oxidation process is a chemical oxidation process which comprises immerging the substrate and the silicon gate structure in a hydrogen peroxide solution, wherein a temperature of the hydrogen peroxide solution is in a range from 25° C. to 80° C.

8. The fabricating method of a semiconductor device as claimed in claim 1, wherein the mask consists of a photoresist material.

9. The fabricating method of a semiconductor device as claimed in claim 8, wherein the cleaning process comprises an ash process which comprises introducing oxygen gas to remove the mask consisting of the photoresist material and the ash process is performed at a temperature in a range from 25° C. to 300° C.

10. The fabricating method of a semiconductor device as claimed in claim 1, wherein the dopant implantation process comprises an ion implantation process to form a doped region of a P type or an N type.

11. The fabricating method of a semiconductor device as claimed in claim 1, wherein the method further comprises:
depositing a partitioning wall layer on the substrate and the silicon gate structure; and
performing an anisotropy etching process to remove portions of the partitioning wall layer thereby forming a portioning wall structure on a side surface of the silicon gate structure.

12. The fabricating method of a semiconductor device as claimed in claim 11, wherein the partitioning wall layer comprises a silicon dioxide layer and a silicon nitride layer.

13. The fabricating method of a semiconductor device as claimed in claim 1, wherein the silicon gate structure further comprises a silicon-containing material and a dielectric mask layer disposed on the silicon-containing material.
